(19) United States
(12) Patent Application Publication
(10) Pub. No.: US 2013/0240850 A1
(43) Pub. Date: Sep. 19, 2013

(54) ULTRA-HIGH EFFICIENCY (125%) PHOSPHORESCENT ORGANIC LIGHT EMITTING DIODES USING SINGLET FISSION

(71) Applicants: Stephen R. Forrest, Ann Arbor, MI (US); Yifan Zhang, Ann Arbor, MI (US); Kevin Bergemann, Ann Arbor, MI (US)

(72) Inventors: Stephen R. Forrest, Ann Arbor, MI (US); Yifan Zhang, Ann Arbor, MI (US); Kevin Bergemann, Ann Arbor, MI (US)

(73) Assignee: The Regents of the University of Michigan, Ann Arbor, MI (US)

(21) Appl. No.: 13/788,107

(22) Filed: Mar. 7, 2013

Related U.S. Application Data
(60) Provisional application No. 61/610,122, filed on Mar. 13, 2012.
(60) Provisional application No. 61/663,345, filed on Jun. 22, 2012.

(51) Int. Cl. H01L 51/50

(52) U.S. Cl. CPC H01L 51/5028
USPC 257/40

(57) ABSTRACT

An organic light emitting device (OLED) is provided. The OLED includes, an anode; a cathode; and an emissive layer disposed between the anode and the cathode. The emissive layer includes a singlet fission sensitizer and a triplet emitter. The singlet energy of the singlet fission sensitizer is equal to or greater than twice the triplet energy of the singlet fission sensitizer. The triplet energy of the triplet emitter is less than the triplet energy of the singlet fission sensitizer.

### CROSS-REFERENCE TO RELATED APPLICATIONS

This application claims benefit under 35 U.S.C. §119(e) of U.S. Provisional Application No. 61/610,122, filed on Mar. 13, 2012 and U.S. Provisional Application No. 61/663,345, filed on Jun. 22, 2012, the entire disclosures of which are incorporated herein by reference for all purposes.

### GOVERNMENT RIGHTS

This invention was made with government support under DE-SC0001013 awarded by the Department of Energy. The government has certain rights in the invention.

### JOINT RESEARCH AGREEMENTS

The claimed invention was made by, on behalf of, and/or in connection with one or more of the following parties to a joint university corporation research agreement: Regents of the University of Michigan, Princeton University, University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to organic light emitting diodes (OLEDs).

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

An organic light emitting device (OLED) is provided. The OLED includes, an anode; a cathode; and an emissive layer disposed between the anode and the cathode. The emissive layer includes a singlet fission sensitizer and a triplet emitter. The singlet energy of the singlet fission sensitizer is equal to or greater than twice the triplet energy of the singlet fission sensitizer. The triplet energy of the triplet emitter is less than the triplet energy of the singlet fission sensitizer.

Preferably, the singlet energy of the singlet fission sensitizer is within 0.5 eV of the twice the triplet energy of the singlet fission sensitizer.\

Preferably, the triplet energy of the singlet fission sensitizer is less than 1.7 eV and the triplet energy of the triplet emitter is less than 1.6 eV.

In one embodiment, the singlet fission sensitizer is a host and the triplet emitter is a dopant in the emissive layer. The emissive layer may consist essentially of the singlet fission sensitizer uniformly doped with the triplet emitter.

Or, the emissive layer may comprise a first sublayer and a second sublayer, where: the first sublayer consists essentially of the singlet fission sensitizer, and the second sublayer consists essentially of the singlet fission sensitizer uniformly doped with the triplet emitter. The emissive layer may consist essentially of the first sublayer and the second sublayer, or may include additional layers. The emissive layer may comprise a plurality of alternating first sublayers and second sublayers, where:the first sublayer consists essentially of the singlet fission sensitizer, and the second sublayer consists essentially of the singlet fission sensitizer uniformly doped with the triplet emitter.

Examples of appropriate singlet fission sensitizer and triplet emitter materials are provided herein. Other materials may be used.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows excitonic transfer pathways for the proposed OLED with singlet fission and triplet emission processes. Excitons (both singlets and triplets) are formed on host singlet fission sensitizer, where efficient singlet fission happens and one singlet forms two triplets. Subsequently, the triplets on the sensitizer transfer to guest triplet emitter where efficient radiative emission happens.

FIG. 4 shows four proposed device structures for realizing the energy transfer pathways described in FIG. 1.

FIG. 5 shows an energetic route for reaching the 125% high efficiency phosphorescent OLEDs.

FIG. 6 shows an energetic route for reaching the 125% high efficiency phosphorescent OLEDs.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

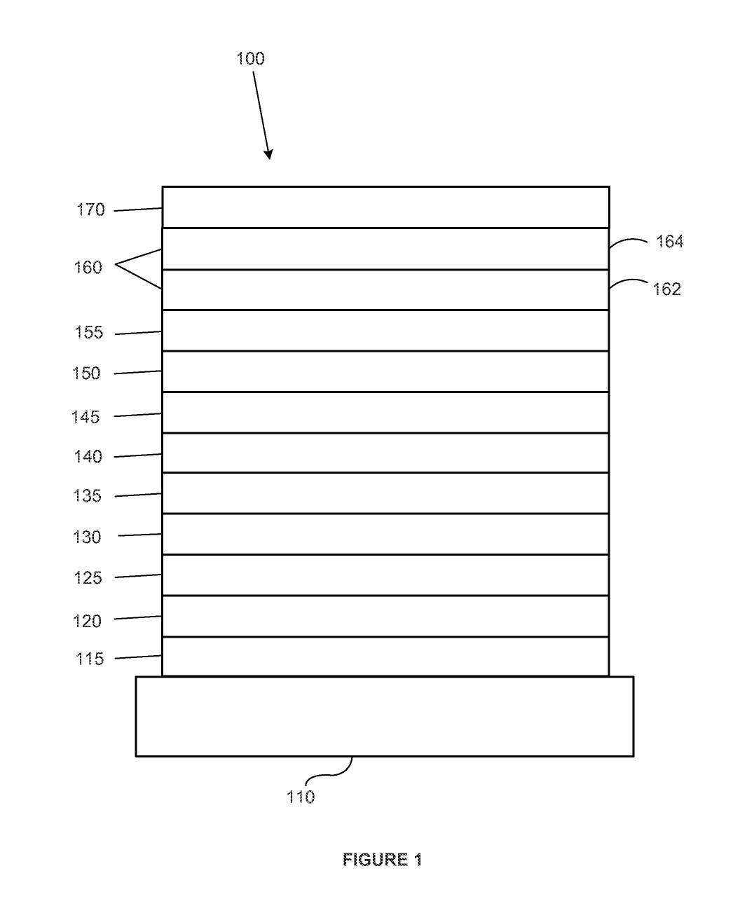

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F.sub.4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

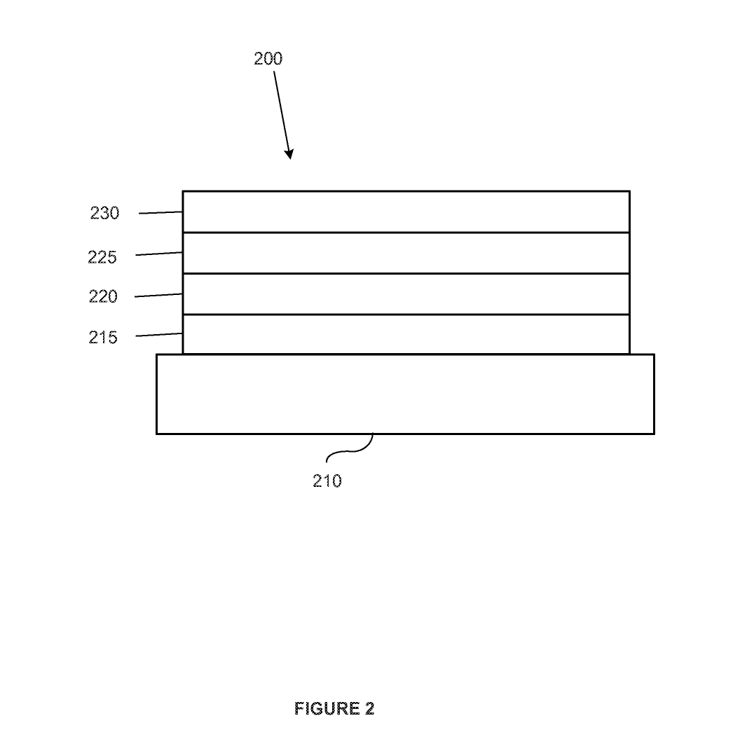

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. patent application Ser. No. 10/233,470, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the invention may be incorporated into a wide variety of consumer products, including flat panel displays, computer monitors, medical monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.).

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

The terms halo, halogen, alkyl, cycloalkyl, alkenyl, alkynyl, arylkyl, heterocyclic group, aryl, aromatic group, and heteroaryl are known to the art, and are defined in U.S. Pat. No. 7,279,704 at cols. 31-32, which are incorporated herein by reference.

A novel excitonic energy transfer pathway in organic light emitting diodes that utilizes both singlet fission and triplet emission is described herein. In such a device, upon current injection, 25% of recombination forms singlets and 75% of recombination forms triplets. Subsequently, one singlet undergoes fission and forms two triplets, thus the quantum efficiency limit for the OLEDs can reach 25%×2+75%=125%. Several multi-layer OLEDs structures with material choice criteria are provided.

Singlet fission is a process in which a molecule in its singlet excited state (or singlet) shares its excitation energy with a neighboring ground-state molecule and both are converted into triplet excited states (or triplets), as described in M. Pope, and C. E. Swenberg, Electronic Processes in Organic Crystals and Polymers (Oxford University Press, 1999), Second edn. (“Pope”); and M. B. Smith, and J. Michl, Chem. Rev. 110 6891 (2010) (“Smith”). In the present disclosure, a novel excitonic energy transfer pathway involving both singlet fission and triplet emission is described that pushes the quantum efficiency (defined as the ratio between the number of output photons and input electrons per unit time) limit of single emission layer OLEDs to as high as 125%.

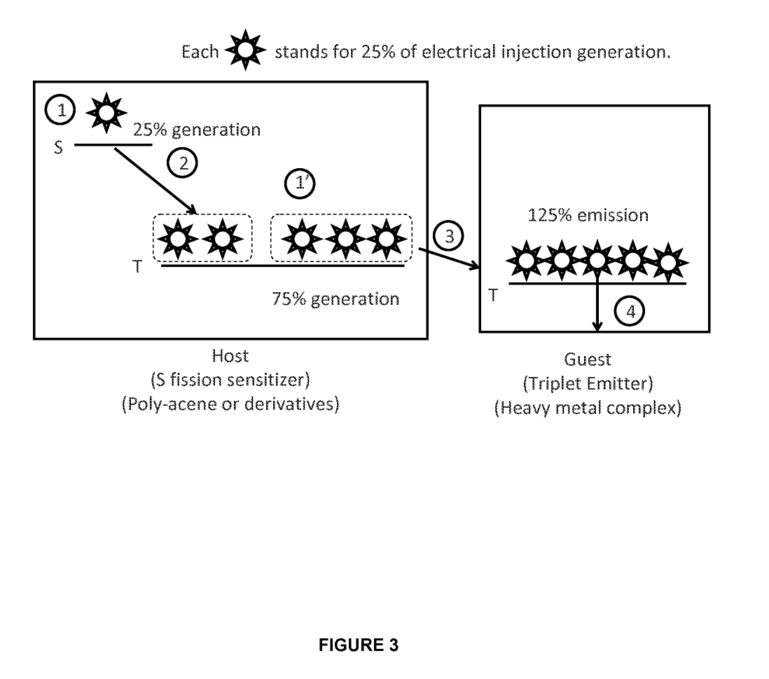

In one embodiment, OLEDs utilizing this special energy transfer pathway may have an emission layer (EML) comprising a binary mix: a singlet fission sensitizer as host and a triplet emitter as dopant (see FIG. 3). The triplet emitter is doped in the singlet fission sensitizer at preferably 0.5%-30% (by volume) concentration. Electron-hole recombination may happen on host, where 25% of recombination forms singlets and 75% of the recombination forms triplets. Then, efficient singlet fission happens and each, or most of, of the initially formed singlets turns into two triplets. Now, for one electron-hole recombination event, 1.25 of triplets end on the host; subsequently, these triplets transfer to the guest triplet emitter where radiative decay happens, leading to 125% internal quantum efficiency upper limit.

One material criteria for the singlet fission sensitizer is that its singlet energy is equal to or slightly (<0.5 eV) larger than twice its triplet energy. It is known that some polyacene molecules and their derivatives, including but not limited totetracene, rubrene, pentacene, diphenyltetracene have efficient singlet fission properties. See Pope; Smith; P. M. Zimmerman, Z. Zhang, and C. B. Musgrave, Nat Chem 2 648 (2010) (“Zimmerman”); J. Lee, P. Jadhav, and M. A. Baldo, Appl. Phys. Lett. 95 033301 (2009) (“Lee”). The rate of singlet fission can be as fast as approximately 100 fs. See, W.-L. Chan et al., Science 334 1541 (2011) (“Chan”). Other desirable criteria for the triplet emitter is its triplet has high radiative efficiency and is lower in energy than the triplet energy of the fission sensitizer. Typically, the triplet energy of the polyacene molecules preferably used as singlet fission sensitizer is lower than 1.7 eV; thus the triplet emitter triplet energy should preferably be <1.6 eV. The molecular designs can also be realized by use of heavy metal complexes with suitable energetics. See, S. Lamansky et al., J. Am. Chem. Soc. 123 4304 (2001) (“Lamamnsky”); C. Borek et al., Angewandte Chemie-International Edition 46 1109 (2007) (“Borek”). In general, the criteria that the singlet energy be at least about twice that of the triplet means that high energy singlet materials are preferably used in conjunction with appropriate phosphors.

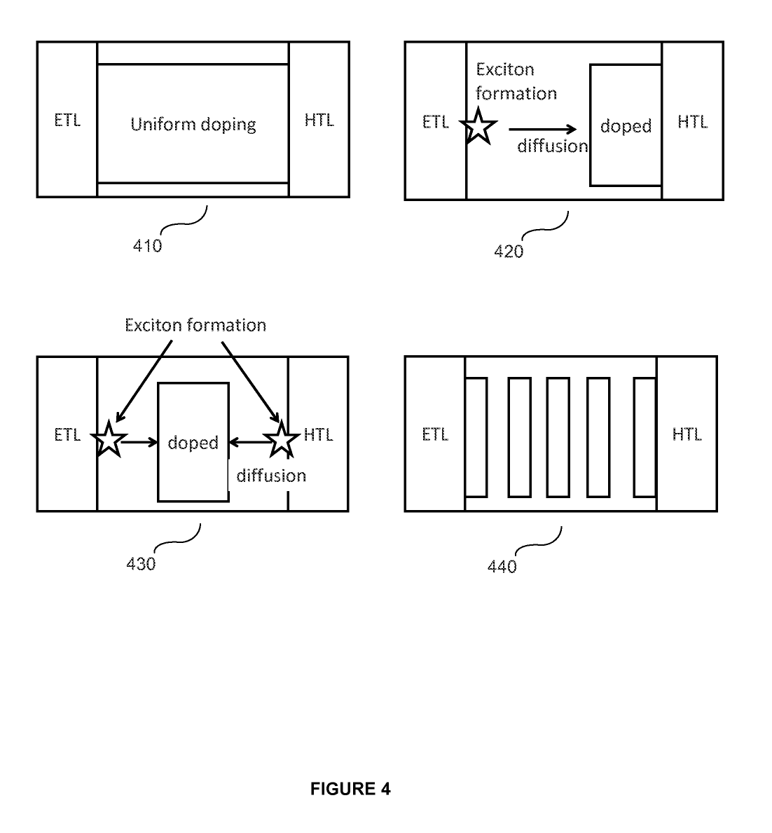

Several device structures are described for realizing the proposed energy transfers. Layers other than the emissive layer, such as the anode, cathode, electron and hole transporting layers structures are preferably the same as for typical OLEDs. The OLEDs utilizing singlet fission is special in its emitting layers (see FIG. 4). Structure 410 shows uniform exciton formation on a host singlet fission sensitizer in the EML. The triplet emitter is doped in the host, preferably uniformly. This structure has the advantage of efficient triplet transfer from host to guest but may suffer the loss channel of singlet direct transfer from the host to guest without fission. FIG. 4, structures 420, 430 and 440, show the emissive layers with separated exciton formation and emission regions. Exciton formation often occurs at or near interfaces, and a device can be designed to control where exciton formation occurs. Initially, excitons are formed at the ETL/EML and/or the HTL/EML interface, in a region where the host singlet fission sensitizer is not doped with the triplet emitter. Exciton formation and singlet fission happens in such a region, then triplets diffuse from the interface to the doped region where emission happens. These structure could eliminate the host singlet to guest singlet direct transfer loss, but the triplet transfer from host to emitter may not be as efficient as for structure 1. FIG. 4, structure 440 provides additional interfaces and multiple regions where excitons may form, where singlet fission may occur on the singlet fission sensitizer without the presence of a triplet emitter, and where the triplet emitter may emit.

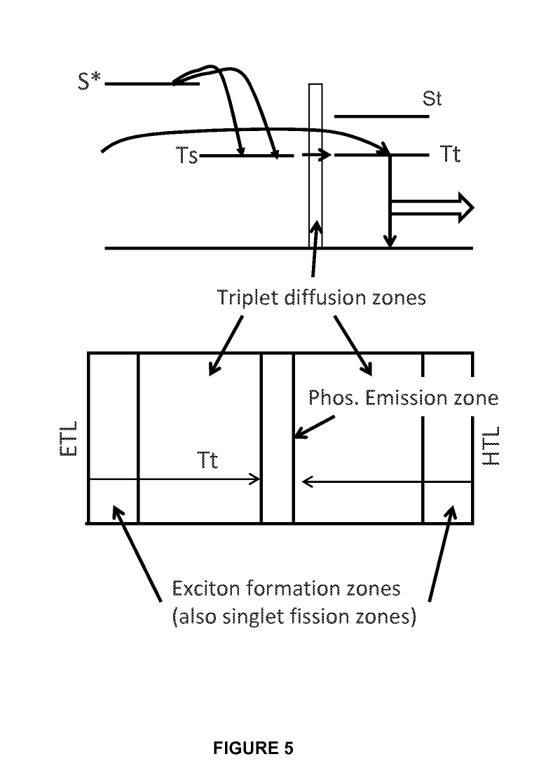

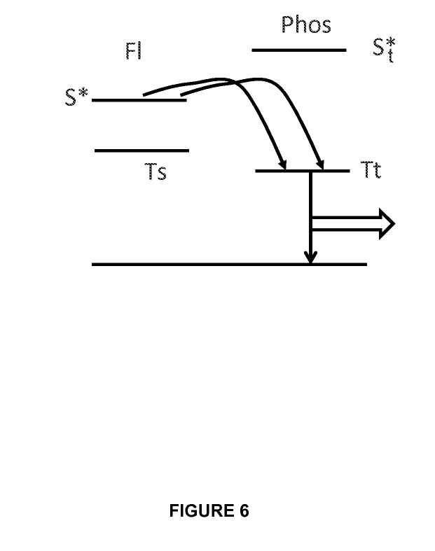

FIG. 5 shows an approaches for phosphorescent OLEDs using singlet fission. A host singlet fission sensitizer and guest triplet emitter are present. The sensitizer singlet energy S* is equal to or slightly (within 0.5 eV) larger than twice its triplet energy Ts. The guest emitter's triplet energy Tt is preferably equal to or smaller than the triplet energy Ts of the host sensitizer, though endothermic energetics with the guest triplet energy larger than host triplet energy is also possible. The guest's singlet energy is lower than the singlet energy St of the host. In one device structure, the EML may consist of two host-only exciton formation regions on two sides, near interfaces with layers other than the emissive layer at which recombination may be likely, then two host-only triplet diffusion zones, and a host-guest phosphorescent (triplet) emission zone in the middle. Excitons (both singlets and triplets) initially are formed on one or both sides of the EML, Singlets undergo rapid fission and form triplets. Then, all the triplets diffuse through the diffusion zone to the phosphorescent emission zone, where emission happens. The reason to use separate exciton formation and emission zone is to avoid singlet direct Förster transfer from host to guest, which lowers the singlet fission efficiency. FIG. 6 shows different energetics where the guest emitter's singlet energy St* is higher than the singlet energy S* of the host. Then, singlet Förster transfer from host to guest is energetically forbidden. So, the preferred EML structure for this energetics is to uniformly dope the guest emitter into host fission sensitizer, such that the exciton formation and emission zones are the same, as illustrated in FIG. 4, structure 410.

Thus, by carefully selecting singlet fission sensitizer and triplet emitter, as well as proper structure design, OLEDs utilizing singlet fission can potentially reach 125% internal quantum efficiency. A total 125% internal quantum efficiency is based on 100% singlet fission efficiency in singlet fission sensitizer and 100% triplet radiative efficiency in triplet emitter.

An organic light emitting device (OLED) is provided. The OLED includes, an anode; a cathode; and an emissive layer disposed between the anode and the cathode. The emissive layer includes a singlet fission sensitizer and a triplet emitter. The singlet energy of the singlet fission sensitizer is equal to or greater than twice the triplet energy of the singlet fission sensitizer. The triplet energy of the triplet emitter is less than the triplet energy of the singlet fission sensitizer.

Preferably, the singlet energy of the singlet fission sensitizer is within 0.5 eV of the twice the triplet energy of the singlet fission sensitizer.\

Preferably, the triplet energy of the singlet fission sensitizer is less than 1.7 eV and the triplet energy of the triplet emitter is less than 1.6 eV.

In one embodiment, the singlet fission sensitizer is a host and the triplet emitter is a dopant in the emissive layer. The emissive layer may consist essentially of the singlet fission sensitizer uniformly doped with the triplet emitter.

As used herein, an emitting layer “consisting essentially of a group of materials means that the emitting layer does not include any other materials or impurities that significantly interfere with or otherwise affect energy transfer pathways and their utilization in the emitting layer. As used herein, an emissive layer that “consists essentially of multiple sublayers does not include any layers in addition to those specifically recited that materially affect the emissive properties of the layer. A device having an emissive layer consisting essentially of one or more sublayers may include further layers in the device, such as injection layers and transport layers. Where a composition or layer is described as “consisting essentially of particular components, it is preferred that those components are the only components present.

Or, the emissive layer may comprise a first sublayer and a second sublayer, where: the first sublayer consists essentially of the singlet fission sensitizer, and the second sublayer consists essentially of the singlet fission sensitizer uniformly doped with the triplet emitter. The emissive layer may consist essentially of the first sublayer and the second sublayer, or may include additional layers. The emissive layer may comprise a plurality of alternating first sublayers and second sublayers, where:the first sublayer consists essentially of the singlet fission sensitizer, and the second sublayer consists essentially of the singlet fission sensitizer uniformly doped with the triplet emitter.

### Materials for Singlet Fission

The singlet fission sensitizer may be selected from the group consisting of: polyacene molecules and their derivatives, including but not limited to tetracene, rubrene, pentacene, diphenyltetracene. Other examples of molecules appropriate for use as a singlet fission sensitizer are listed in Thompson US2009/044864, paras. 0066-0067, which are incorporated by reference. Thompson US2009/044864 is incorporated by reference in its entirety.

In one embodiment, the singlet fission sensitizer satisfies the condition of E(S₁), E(T₂)>2E(T₁). In a further embodiment the singlet fission sensitizer is selected from o-xylylene, p-xylylene, isobenzofulvene, perylene, polythiophene and polyacenes, such as tetracene, p-sexiphenyl, tetracyano-p-quinodimethane, tetrafluoro tetracyano-p-quinodimethane, polydiacetylene, poly(p-phenylene), poly(p-phenylenevinylene), carotenoids, 1,4-bis(tetracen-5-yl)benzene. In one embodiment, the singlet fission sensitizer is selected from the following compounds:

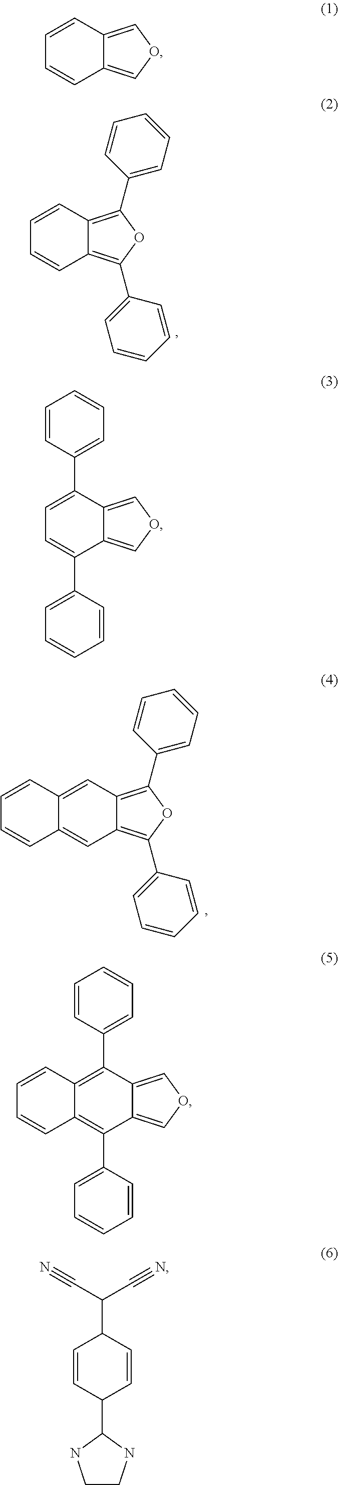

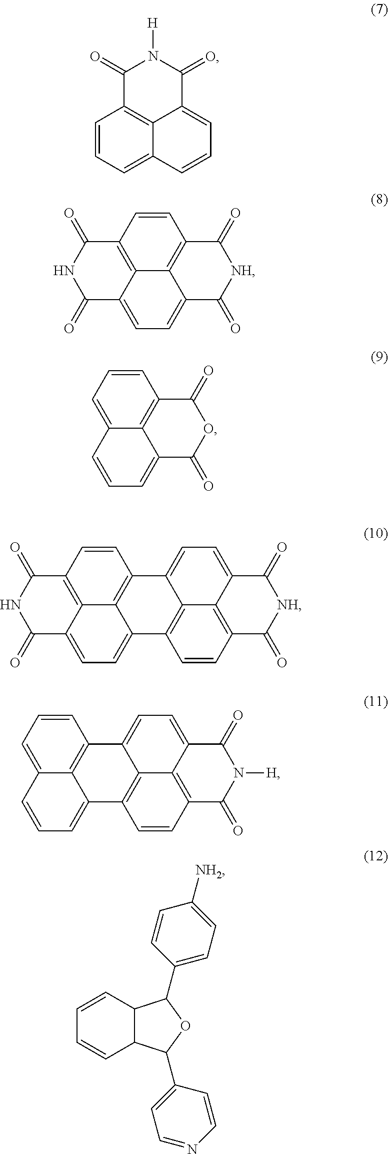

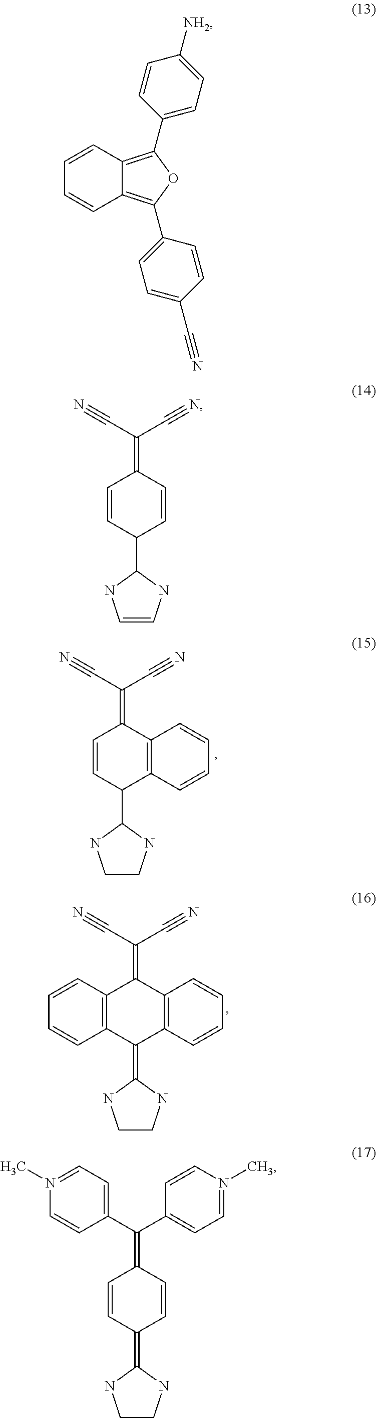

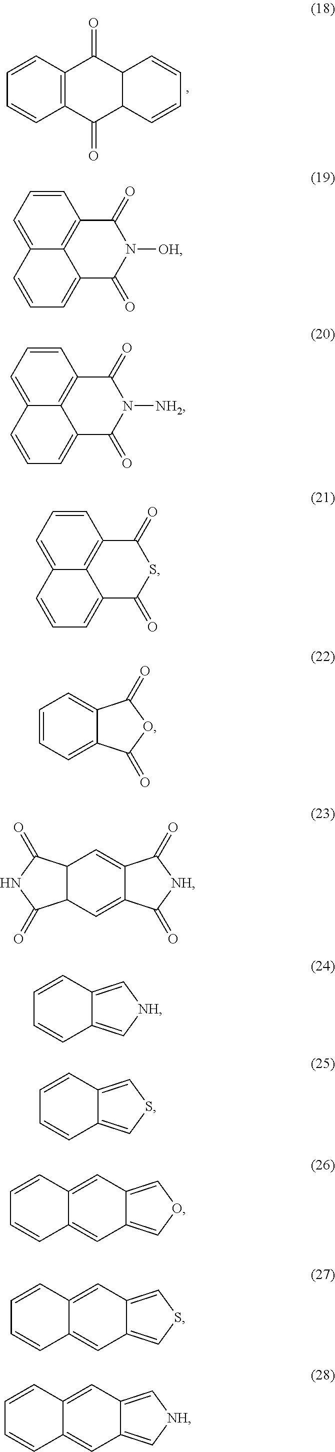

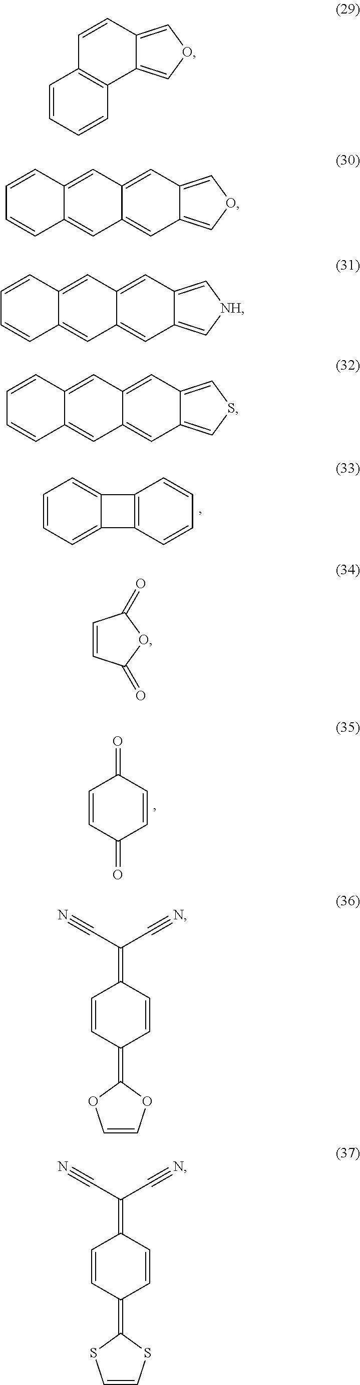

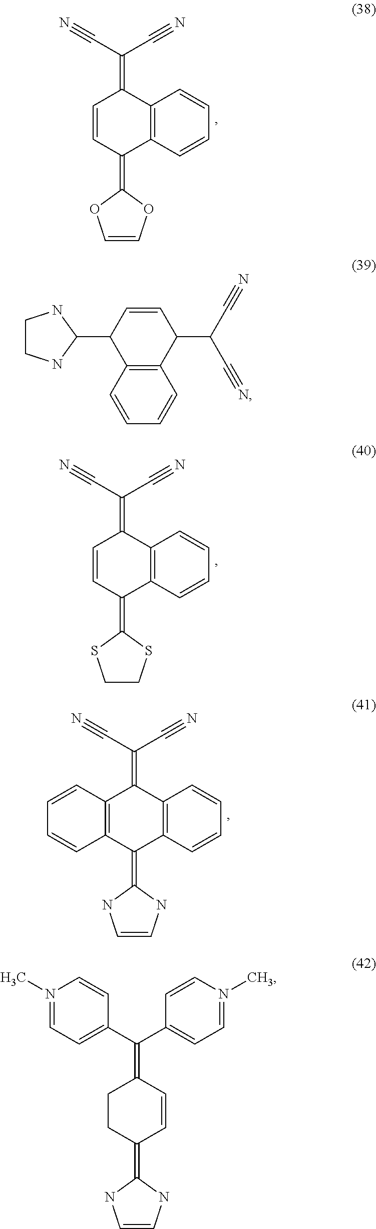

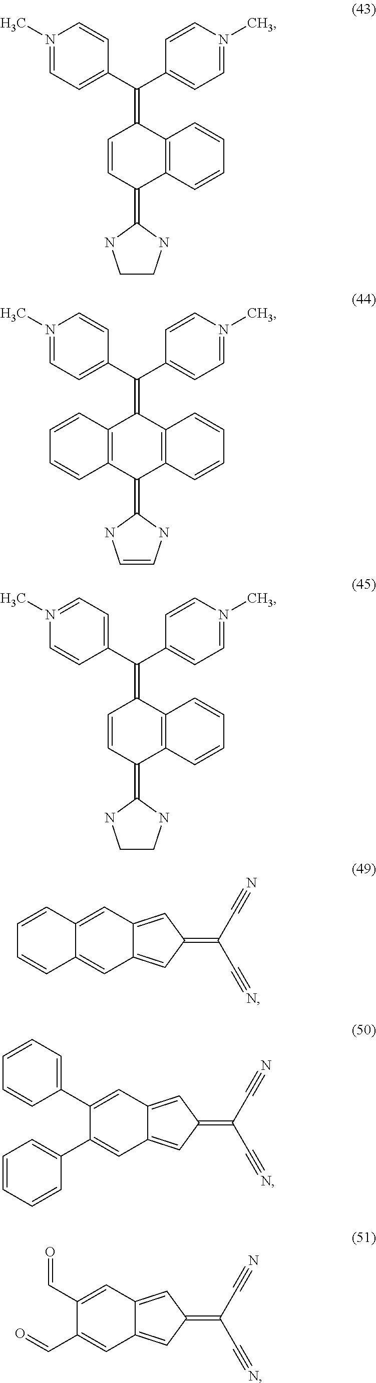

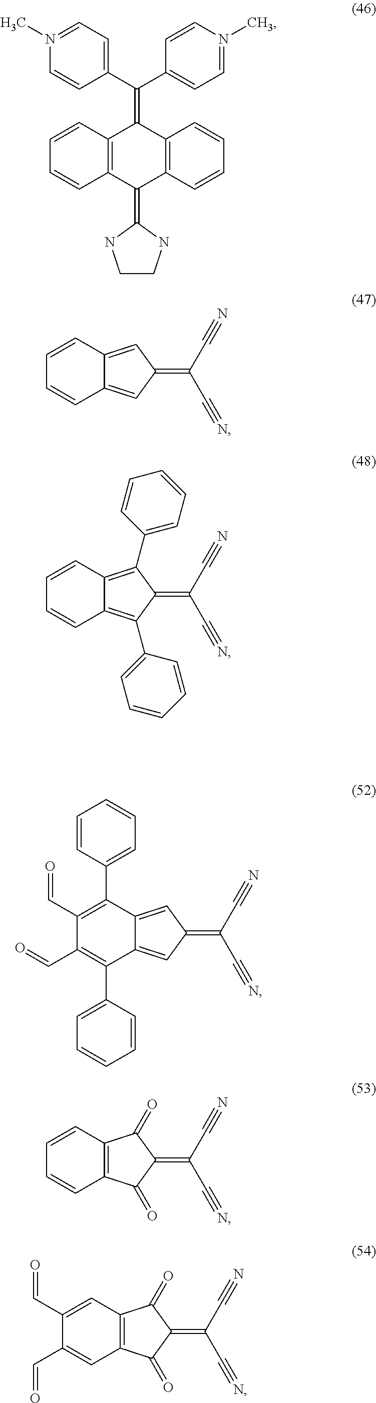

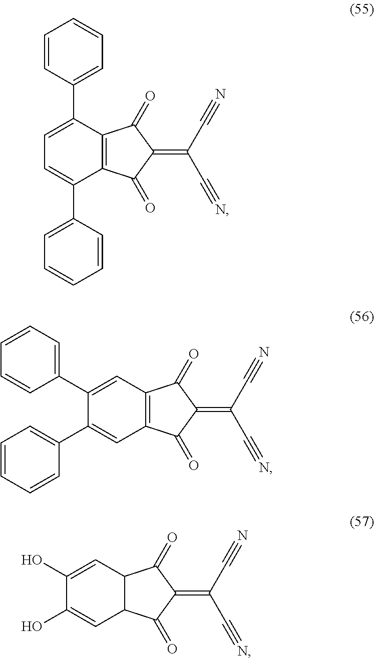 [SMILES: N#CC(C#N)=C1C(=O)c2c(-c3ccccc3)ccc(-c3ccccc3)c2C1=O ; N#CC(C#N)=C1C(=O)c2cc(-c3ccccc3)c(-c3ccccc3)cc2C1=O ; N#CC(C#N)=C1C(=O)C2C=C(O)C(O)=CC2C1=O]

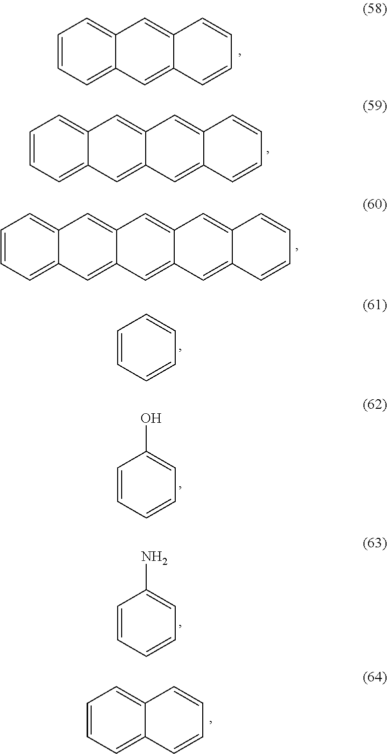

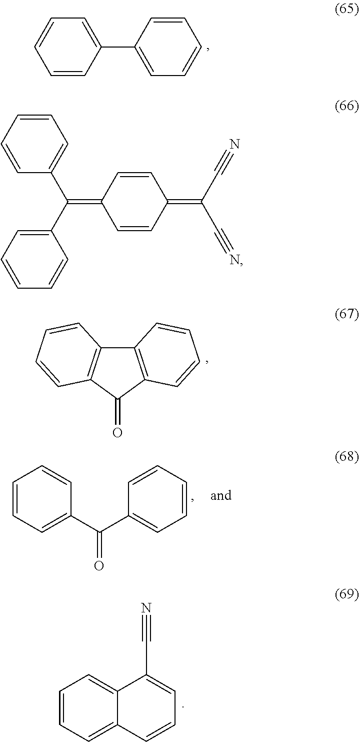

In another embodiment, singlet fission sensitizer is selected from the group consisting of anthracene, tetracene and pentacene. In a further embodiment, the at least one singlet fission host material is selected from crystalline anthracene, crystalline tetracene, and crystalline pentacene.

Examples of molecules appropriate for use as a triplet emitter, also referred to as a triplet forming dopant material, are listed in Thompson US2009/044864, paras. 0068-0107, which are incorporated by reference.

In another embodiment, the at least one triplet forming dopant material has a higher triplet energy than that of the at least one singlet fission host material. In another embodiment, the at least one triplet forming dopant material has a small singlet-triplet gap, for example a singlet-triplet gap of less than about 0.5 eV. In one embodiment, the triplet forming dopant material has the right energetics relative to the singlet fission host material so that the dopant material's triplet will transfer exothermically to the triplet of the singlet fission host material. Examples of the triplet forming dopant material that can be used in the devices of the present invention can be, but are not limited to porphyrins and phthalocyanines In another embodiment, a triplet forming dopant material other than a porphyrin or phthalocyanine complex will work in the devices of the present invention.

In one embodiment, the at least one triplet forming dopant material absorbs light in the red and near IR regions of the solar spectrum.

In another embodiment, the at least one triplet forming dopant material is selected from porphyrin compounds and phthalocyanine complexes.

In another embodiment, the at least one triplet forming dopant material is at least one porphyrin compound.

In another embodiment, the at least one porphyrin compound is nonplanar.

In another embodiment, the at least one nonplanar porphyrin is selected from compounds having formula (I),

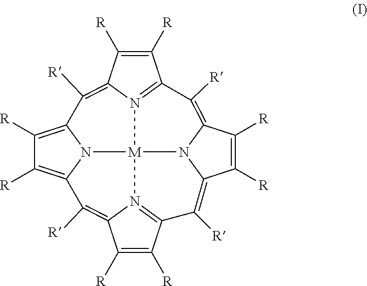

wherein M is selected from Sc, Y, La, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Hg, Al, Ga, In, TI, Si, Ge, Sn, Pb, P, As, Sb, Bi, S, Se, Te, Po, Cl, Br, I, At, lanthanides, actinides, and 2H; R′ is independently selected from Cl, Br, I, At, and a group comprising a valence atom attached to the meso carbon of the porphyrin, wherein the valence atom is selected from B, C, N, O, Si, P, S, Cl, Ge, As, Se, Br, In, Sn, Sb, Te, I, TI, Pb, Bi, Po and At; and R is independently selected from Cl, Br, I, At, and a group comprising a valence atom attached to a .beta. carbon of a pyrrole ring, wherein the valence atom is selected from B, C, N, O, Si, P, S, Cl, Ge, As, Se, Br, In, Sn, Sb, Te, I, TI, Pb, Bi, Po and At, wherein two adjacent R groups attached to the same pyrrole ring together with the two .beta. carbons of the pyrrole ring may form a carbocyclic group or heterocyclic group.

As shown in Formula I, 2H comprise the two non-covalently linked nitrogen atoms (shown with dashed lines) that have hydrogen atoms.

In another embodiment, the valence atom in at least one R′ or R group is C.

In one embodiment, the at least one R′ or R group is independently selected from an alkyl group, substituted alkyl group, alkenyl group, substituted alkenyl group, alkynyl group, substituted alkynyl group, cycloalkyl group, substituted cycloalkyl group, cycloalkenyl group, substituted cycloalkenyl group, cycloalkynyl group, substituted cycloalkynyl group, aryl group, substituted aryl group, heterocyclic group and substituted heterocyclic group.

In another embodiment, the substituted alkyl group is substituted with at least one radical independently selected from cycloalkyl groups, cycloalkenyl groups, cycloalkynyl groups, aryl groups, heterocyclic groups, hydroxy groups, alkoxy groups, alkenyloxy groups, alkynyloxy groups, cycloalkoxy groups, cycloalkenyloxy groups, cycloalkynyloxy groups, aryloxy groups, alkylcarbonyloxy groups, cycloalkylcarbonyloxy groups, cycloalkenylcarbonyloxy groups, cycloalkynylcarbonyloxy groups, arylcarbonyloxy groups, thiol group, alkylthio groups, cycloalkylthio groups, cycloalkenylthio groups, cycloalkynylthio groups, arylthio groups, formyl group, acyl group, carbamoyl groups, amino groups optionally substituted with at least one alkyl group, alkenyl group or alkynyl group, acylamino groups, N-acyl-N-alkyl amino groups, N-acyl-N-alkenyl amino groups, N-acyl-N-alkynyl amino groups, N-acyl-N-cycloalkyl amino groups, N-acyl-N-cycloalkenyl amino groups, N-acyl-N-aryl amino groups, nitro groups, heterocyclic groups and halogen atoms;

the substituted alkenyl group is substituted with at least one radical independently selected from cycloalkyl groups, cycloalkenyl groups, cycloalkynyl groups, aryl groups, heterocyclic groups, hydroxy group, alkoxy groups, alkenyloxy groups, alkynyloxy groups, cycloalkoxy groups, cycloalkenyloxy groups, cycloalkynyloxy groups, aryloxy groups, alkylcarbonyloxy groups, cycloalkylcarbonyloxy groups, cycloalkenylcarbonyloxy groups, cycloalkynylcarbonyloxy groups, arylcarbonyloxy groups, thiol group, alkylthio groups, cycloalkylthio groups, cycloalkenylthio groups, cycloalkynylthio groups, arylthio groups, formyl group, acyl groups, carbamoyl groups, amino groups optionally substituted with at least one alkyl group, alkenyl group or alkynyl group, acylamino groups, N-acyl-N-alkyl amino groups, N-acyl-N-alkenyl amino groups, N-acyl-N-alkynyl amino groups, N-acyl-N-cycloalkyl amino groups, N-acyl-N-cycloalkenyl amino groups, N-acyl-N-aryl amino groups, nitro group, heterocyclic groups and halogen atoms;

the substituted alkynyl group is substituted with at least one radical independently selected from cycloalkyl groups, cycloalkenyl groups, cycloalkynyl groups, aryl groups, heterocyclic groups, hydroxy group, alkoxy groups, alkenyloxy groups, alkynyloxy groups, cycloalkoxy groups, cycloalkenyloxy groups, cycloalkynyloxy groups, aryloxy groups, alkylcarbonyloxy groups, cycloalkylcarbonyloxy groups, cycloalkenylcarbonyloxy groups, cycloalkynylcarbonyloxy groups, arylcarbonyloxy groups, thiol group, alkylthio groups, cycloalkylthio groups, cycloalkenylthio groups, cycloalkynylthio groups, arylthio groups, formyl group, acyl groups, carbamoyl groups, amino groups optionally substituted with at least one alkyl group, alkenyl group or alkynyl group, acylamino groups, N-acyl-N-alkyl amino groups, N-acyl-N-alkenyl amino groups, N-acyl-N-alkynyl amino groups, N-acyl-N-cycloalkyl amino groups, N-acyl-N-cycloalkenyl amino groups, N-acyl-N-aryl amino groups, nitro group, heterocyclic groups and halogen atoms;

the substituted cycloalkyl group is substituted with at least one radical independently selected from alkyl groups, alkenyl groups, alkynyl groups, cycloalkyl groups, cycloalkenyl groups, cycloalkynyl groups, aryl groups, heterocyclic groups, hydroxy group, alkoxy groups, alkenyloxy groups, alkynyloxy groups, cycloalkoxy groups, cycloalkenyloxy groups, cycloalkynyloxy groups, aryloxy groups, alkylcarbonyloxy groups, cycloalkylcarbonyloxy groups, cycloalkenylcarbonyloxy groups, cycloalkynylcarbonyloxy groups, arylcarbonyloxy groups, thiol group, alkylthio groups, cycloalkylthio groups, cycloalkenylthio groups, cycloalkynylthio groups, arylthio groups, formyl group, acyl groups, carbamoyl groups, amino groups optionally substituted with at least one alkyl group, alkenyl group or alkynyl group, acylamino groups, N-acyl-N-alkyl amino groups, N-acyl-N-alkenyl amino groups, N-acyl-N-alkynyl amino groups, N-acyl-N-cycloalkyl amino groups, N-acyl-N-cycloalkenyl amino groups, N-acyl-N-aryl amino groups, nitro group, heterocyclic groups and halogen atoms;

the substituted cycloalkenyl group is substituted with at least one radical independently selected from alkyl groups, alkenyl groups, alkynyl groups, cycloalkyl groups, cycloalkenyl groups, cycloalkynyl groups, aryl groups, heterocyclic groups, hydroxy group, alkoxy groups, alkenyloxy groups, alkynyloxy groups, cycloalkoxy groups, cycloalkenyloxy groups, cycloalkynyloxy groups, aryloxy groups, alkylcarbonyloxy groups, cycloalkylcarbonyloxy groups, cycloalkenylcarbonyloxy groups, cycloalkynylcarbonyloxy groups, arylcarbonyloxy groups, thiol group, alkylthio groups, cycloalkylthio groups, cycloalkenylthio groups, cycloalkynylthio groups, arylthio groups, formyl group, acyl groups, carbamoyl groups, amino groups optionally substituted with at least one alkyl group, alkenyl group or alkynyl group, acylamino groups, N-acyl-N-alkyl amino groups, N-acyl-N-alkenyl amino groups, N-acyl-N-alkynyl amino groups, N-acyl-N-cycloalkyl amino groups, N-acyl-N-cycloalkenyl amino groups, N-acyl-N-aryl amino groups, nitro group, heterocyclic groups and halogen atoms;

the substituted cycloalkynyl group is substituted with at least one radical independently selected from alkyl groups, alkenyl groups, alkynyl groups, cycloalkyl groups, cycloalkenyl groups, cycloalkynyl groups, aryl groups, heterocyclic groups, hydroxy group, alkoxy groups, alkenyloxy groups, alkynyloxy groups, cycloalkoxy groups, cycloalkenyloxy groups, cycloalkynyloxy groups, aryloxy groups, alkylcarbonyloxy groups, cycloalkylcarbonyloxy groups, cycloalkenylcarbonyloxy groups, cycloalkynylcarbonyloxy groups, arylcarbonyloxy groups, thiol group, alkylthio groups, cycloalkylthio groups, cycloalkenylthio groups, cycloalkynylthio groups, arylthio groups, formyl group, acyl groups, carbamoyl groups, amino optionally groups substituted with at least one alkyl group, alkenyl group or alkynyl group, acylamino groups, N-acyl-N-alkyl amino groups, N-acyl-N-alkenyl amino groups, N-acyl-N-alkynyl amino groups, N-acyl-N-cycloalkyl amino groups, N-acyl-N-cycloalkenyl amino groups, N-acyl-N-aryl amino groups, nitro group, heterocyclic groups and halogen atoms;

the substituted aryl group is substituted with at least one radical independently selected from alkyl groups, alkenyl groups, alkynyl groups, cycloalkyl groups, cycloalkenyl groups, cycloalkynyl groups, aryl groups, heterocyclic groups, hydroxy group, alkoxy groups, alkenyloxy groups, alkynyloxy groups, cycloalkoxy groups, cycloalkenyloxy groups, cycloalkynyloxy groups, aryloxy groups, alkylcarbonyloxy groups, cycloalkylcarbonyloxy groups, cycloalkenylcarbonyloxy groups, cycloalkynylcarbonyloxy groups, arylcarbonyloxy groups, thiol group, alkylthio groups, cycloalkylthio groups, cycloalkenylthio groups, cycloalkynylthio groups, arylthio groups, formyl group, acyl groups, carbamoyl groups, amino groups optionally substituted with at least one alkyl group, alkenyl group or alkynyl group, acylamino groups, N-acyl-N-alkyl amino groups, N-acyl-N-alkenyl amino groups, N-acyl-N-alkynyl amino groups, N-acyl-N-cycloalkyl amino groups, N-acyl-N-cycloalkenyl amino groups, N-acyl-N-aryl amino groups, nitro group, heterocyclic groups and halogen atoms; and

the substituted heterocyclic group is substituted with at least one radical independently selected from alkyl groups, alkenyl groups, alkynyl groups, cycloalkyl groups, cycloalkenyl groups, cycloalkynyl groups, aryl groups, heterocyclic groups, hydroxy group, alkoxy groups, alkenyloxy groups, alkynyloxy groups, cycloalkoxy groups, cycloalkenyloxy groups, cycloalkynyloxy groups, aryloxy groups, alkylcarbonyloxy groups, cycloalkylcarbonyloxy groups, cycloalkenylcarbonyloxy groups, cycloalkynylcarbonyloxy groups, arylcarbonyloxy groups, thiol group, alkylthio groups, cycloalkylthio groups, cycloalkenylthio groups, cycloalkynylthio groups, arylthio groups, formyl group, acyl groups, carbamoyl groups, amino groups optionally substituted with at least one alkyl group, alkenyl group or alkynyl group, acylamino groups, N-acyl-N-alkyl amino groups, N-acyl-N-alkenyl amino groups, N-acyl-N-alkynyl amino groups, N-acyl-N-cycloalkyl amino groups, N-acyl-N-cycloalkenyl amino groups, N-acyl-N-aryl amino groups, nitro group, heterocyclic groups and halogen atoms.

In one embodiment, the two adjacent R groups of at least one pyrrole ring together with the two .beta. carbon atoms of the at least one pyrrole ring form a carbocyclic group, substituted carbocyclic group, heterocyclic group, or substituted heterocyclic group. In another embodiment, the two adjacent R groups of the at least one pyrrole ring together with the two .beta. carbon atoms of the at least one pyrrole ring form a carbocyclic group or substituted carbocyclic group.

In one embodiment, the carbocyclic group or substituted carbocyclic group is a macrocycle or benzanulated it-system.

In one embodiment, the carbocyclic group or substituted carbocyclic group is aromatic.

In another embodiment, the two adjacent R groups of the at least one pyrrole ring together with the two .beta. carbon atoms of the at least one pyrrole ring form a heterocyclic group or substituted heterocyclic group.

In one embodiment, the heterocyclic group or substituted heterocyclic group is aromatic.

In one embodiment, the at least one R′ or R group is phenyl, tolyl, xylenyl, mesityl, methyl, ethyl, n-propyl or isopropyl.

In one embodiment, the at least one nonplanar porphyrin is selected from the following compounds:

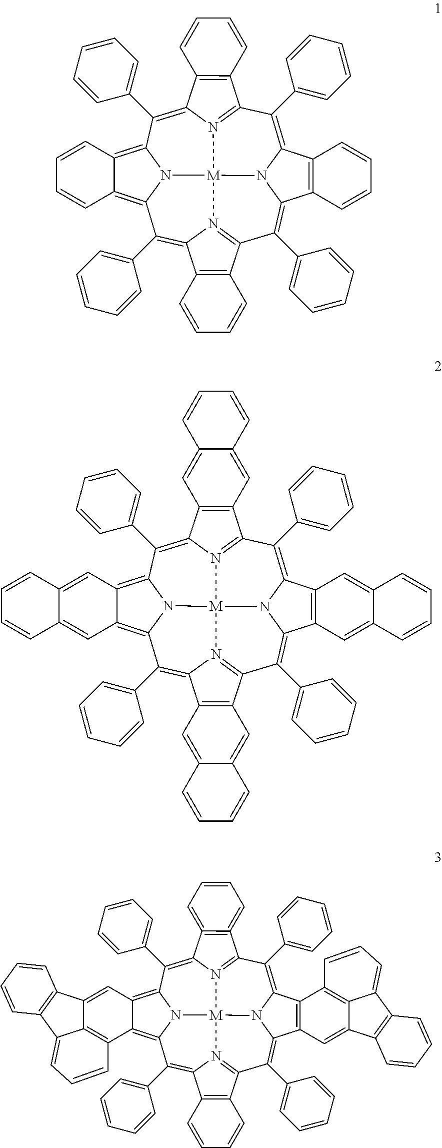

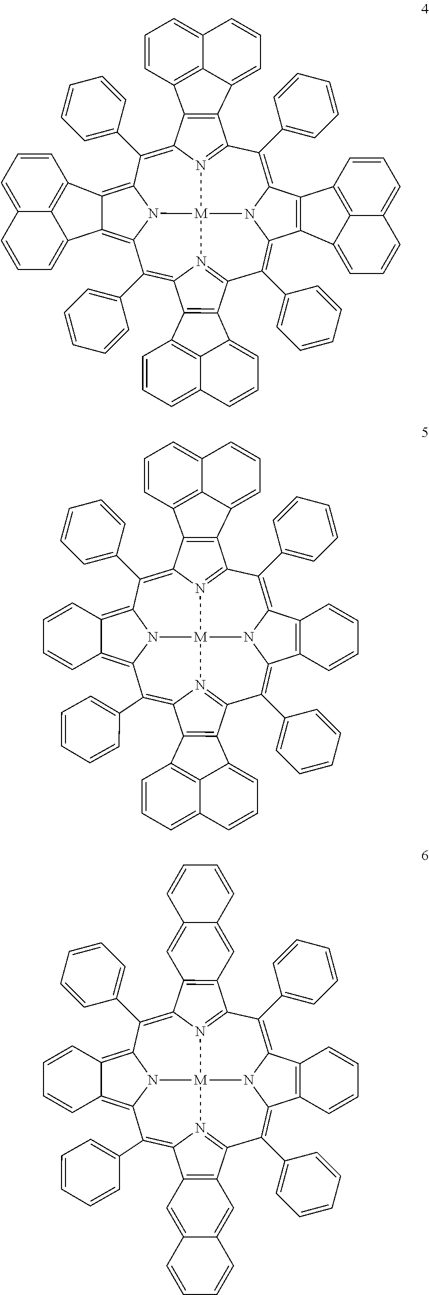

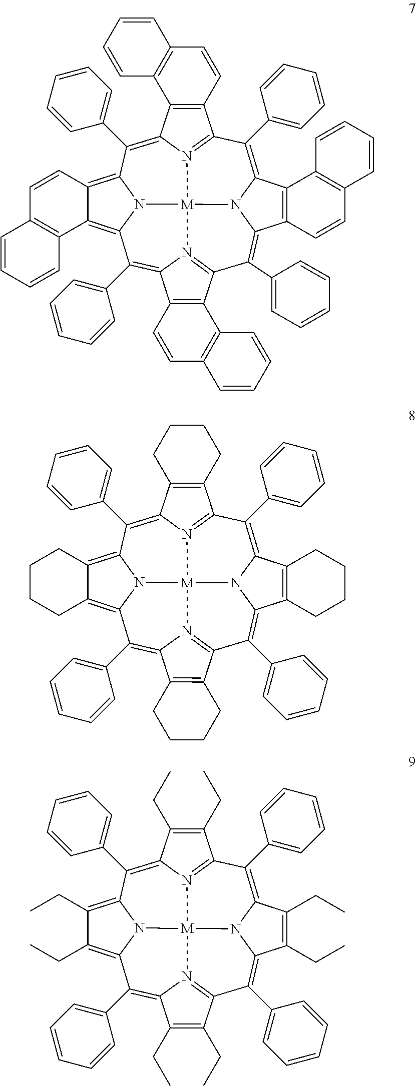

In one embodiment, the valence atom in at least one R′ or R group is O.

In another embodiment, the at least one R′ or R group having O as the valence atom is hydroxy, alkoxy, alkenyloxy, alkynyloxy, cycloakoxy, cycloalkenyloxy, cycloalknyloxy, aralkyloxy, aralkenyloxy, aralkynyloxy, aryloxy, alkylcarbonyloxy, alkenylcarbonyloxy, alkynylcarbonyloxy, hydroxycarbonyloxy or alkoxycarbonyloxy.

In a further embodiment, the at least one R′ or R group having O as the valence atom is hydroxy or alkoxy.

In a further embodiment, the at least one R′ or R group having O as the valence atom is OH, methoxy, ethoxy, n-propoxy or isopropoxy.

In one embodiment, at least one R or R′ group is independently selected from Cl, Br, I, and At.

In another embodiment, at least one R or R′ group has N as the valence atom.

In one embodiment, the at least one R or R′ group having N as the valence atom is selected from an amino group, alkylamino groups, dialkylamino groups, alkenylamino groups, dialkenylamino groups, alkynylamino groups, dialkynylamino groups, N-alkyl-N-alkenylamino groups, N-alkyl-N-alkynylamino groups, N-alkenyl-N-alkynylamino groups, acylamino groups, N-acyl-N-alkyl amino groups, N-acyl-N-alkenyl amino groups, N-acyl-N-alkynyl amino groups, N-acyl-N-cycloalkyl amino groups, N-acyl-N-cycloalkenyl amino groups, N-acyl-N-aryl amino groups, nitro group, heterocyclic groups comprising a nitrogen valence atom and substituted heterocyclic groups comprising a nitrogen valence atom.

In one embodiment, at least one R or R′ group has S as the valence atom.

In one embodiment, the at least one R or R′ group comprising S as the valence atom is selected from a thiol group, alkylthio groups, alkenylthio groups, alkynylthio groups, aralkylthio groups, aralkenylthio groups, aralkynylthio groups, cycloalkylalkylthio groups, cycloalkenylalkylthio groups, cycloalkynylalkylthio groups, cycloalkylthio groups, cycloalkenylthio groups, cycloalkynylthio groups, and arylthio groups.

In one embodiment, M is Pt, Pd, or Ir.

In another embodiment, M is Pt.

In another embodiment, M is Pd.

In one embodiment, the at least one nonplanar porphyrin is Pt(tetraphenyl benzo-porphyrin).

In another embodiment, the at least one nonplanar porphyrin is Pd(tetraphenyl benzo-porphyrin).

Combination with Other Materials

The materials described herein as useful for a particular layer in an organic light emitting device may be used in combination with a wide variety of other materials present in the device. For example, the specific materials and energetic guidelines disclosed herein as useful for obtaining singlet fission may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### HIL/HTL:

A hole injecting/transporting material to be used in the present invention is not particularly limited, and any compound may be used as long as the compound is typically used as a hole injecting/transporting material. Examples of the material include, but not limit to: a phthalocyanine or porphryin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and sliane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

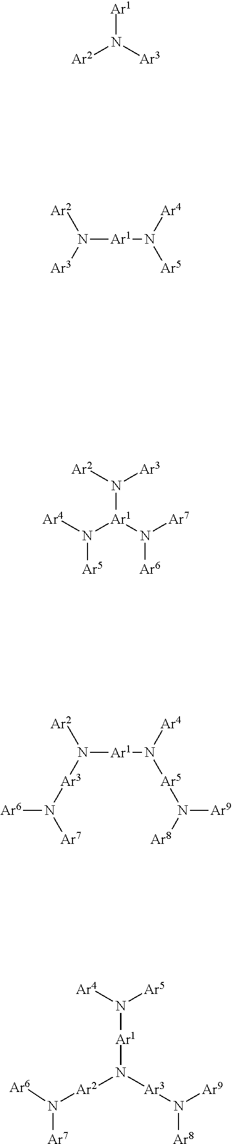

Each of Ar¹ to Ar⁹ is selected from the group consisting aromatic hydrocarbon cyclic compounds such as benzene, biphenyl, triphenyl, triphenylene, naphthalene, anthracene, phenalene, phenanthrene, fluorene, pyrene, chrysene, perylene, azulene; group consisting aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and group consisting 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Wherein each Ar is further substituted by a substituent selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof

In one aspect, Ar¹ to Ar⁹ is independently selected from the group consisting of:

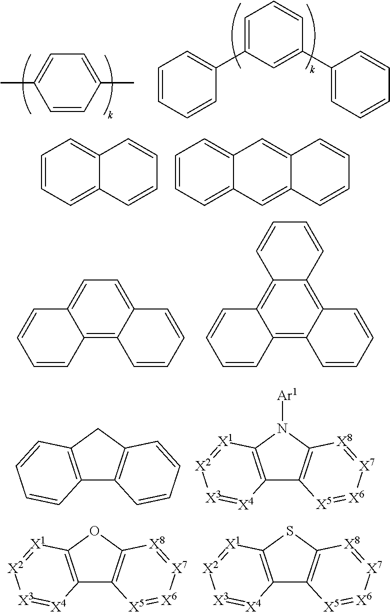

k is an integer from 1 to 20; X¹ to X⁸ is C (including CH) or N; Ar¹ has the same group defined above.

Examples of metal complexes used in HIL or HTL include, but not limit to the following general formula:

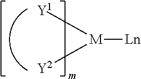

M is a metal, having an atomic weight greater than 40; (Y¹-Y²) is a bidentate ligand, Y¹ and Y² are independently selected from C, N, O, P, and S; L is an ancillary ligand; m is an integer value from 1 to the maximum number of ligands that may be attached to the metal; and m+n is the maximum number of ligands that may be attached to the metal.

In one aspect, (Y¹-Y²) is a 2-phenylpyridine derivative.

In another aspect, (Y¹-Y²) is a carbene ligand.

In another aspect, M is selected from Ir, Pt, Os, and Zn.

In a further aspect, the metal complex has a smallest oxidation potential in solution vs. Fc⁺/Fc couple less than about 0.6 V.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. While the Table below categorizes host materials as preferred for devices that emit various colors, any host material may be used with any dopant so long as the triplet criteria is satisfied.

Examples of metal complexes used as host are preferred to have the following general formula:

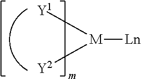

M is a metal; (Y³-Y⁴) is a bidentate ligand, Y³ and Y⁴ are independently selected from C, N, O, P, and S; L is an ancillary ligand; m is an integer value from 1 to the maximum number of ligands that may be attached to the metal; and m+n is the maximum number of ligands that may be attached to the metal.

In one aspect, the metal complexes are:

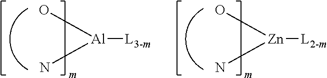

(O—N) is a bidentate ligand, having metal coordinated to atoms O and N.

In another aspect, M is selected from Ir and Pt.

In a further aspect, (Y³-Y⁴) is a carbene ligand.

Examples of organic compounds used as host are selected from the group consisting aromatic hydrocarbon cyclic compounds such as benzene, biphenyl, triphenyl, triphenylene, naphthalene, anthracene, phenalene, phenanthrene, fluorene, pyrene, chrysene, perylene, azulene; group consisting aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and group consisting 2 to 10 cyclic structural units which are groups of the same type or different types selected from the aromatic hydrocarbon cyclic group and the aromatic heterocyclic group and are bonded to each other directly or via at least one of oxygen atom, nitrogen atome, sulfur atom, silicon atom, phosphorus atom, boron atom, chain structural unit and the aliphatic cyclic group. Wherein each group is further substituted by a substituent selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof.

In one aspect, host compound contains at least one of the following groups in the molecule:

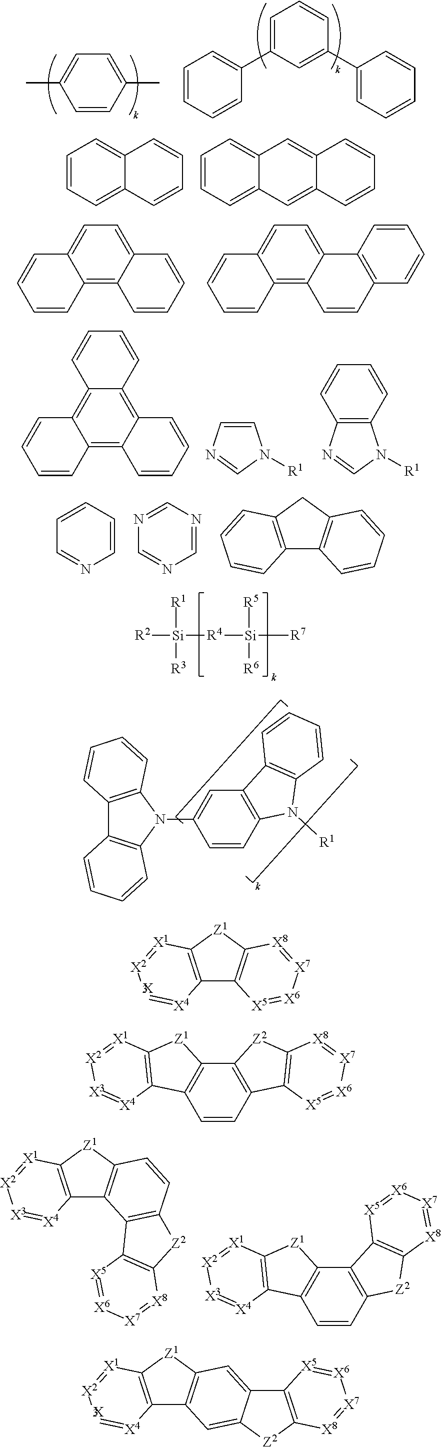

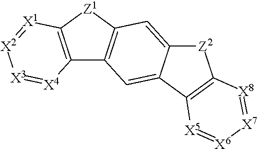

R¹ to R⁷ is independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, when it is aryl or heteroaryl, it has the similar definition as Ar's mentioned above.

k is an integer from 0 to 20.

X¹ to X⁸ is selected from C (including CH) or N.

Z¹ and Z² is selected from NR¹, O, or S.

### HBL:

A hole blocking layer (HBL) may be used to reduce the number of holes and/or excitons that leave the emissive layer. The presence of such a blocking layer in a device may result in substantially higher efficiencies as compared to a similar device lacking a blocking layer. Also, a blocking layer may be used to confine emission to a desired region of an OLED.

In one aspect, compound used in HBL contains the same molecule or the same functional groups used as host described above.

In another aspect, compound used in HBL contains at least one of the following groups in the molecule:

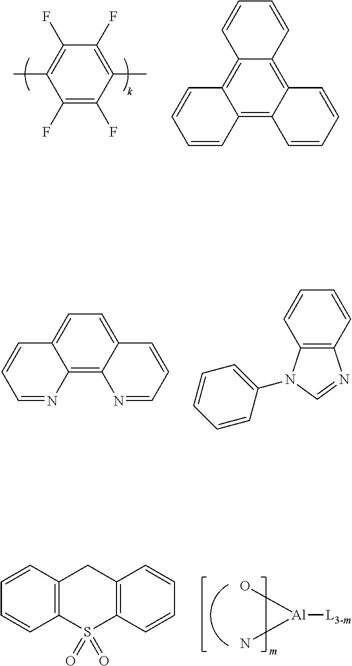

k is an integer from 0 to 20; L is an ancillary ligand, m is an integer from 1 to 3.

### ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

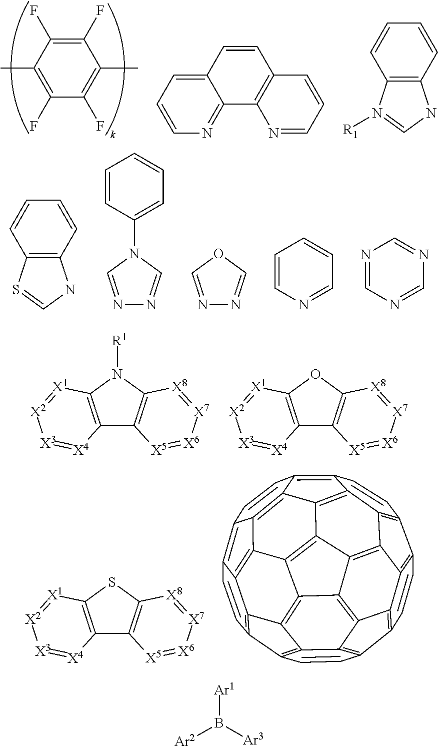

R¹ is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, when it is aryl or heteroaryl, it has the similar definition as Ar's mentioned above.

Ar¹ to Ar³ has the similar definition as Ar's mentioned above.

k is an integer from 0 to 20.

X¹ to X⁸ is selected from C (including CH) or N.

In another aspect, the metal complexes used in ETL contains, but not limit to the following general formula:

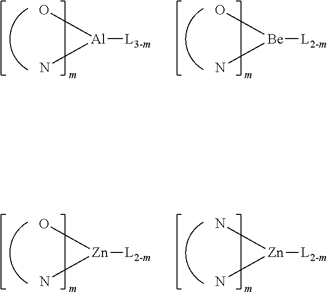

(O—N) or (N—N) is a bidentate ligand, having metal coordinated to atoms O, N or N, N; L is an ancillary ligand; m is an integer value from 1 to the maximum number of ligands that may be attached to the metal.

In any above-mentioned compounds used in each layer of the OLED device, the hydrogen atoms can be partially or fully deuterated.

In addition to and/or in combination with the materials disclosed herein, many hole injection materials, hole transporting materials, host materials, dopant materials, exiton/hole blocking layer materials, electron transporting and electron injecting materials may be used in an OLED.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. An organic light emitting device comprising:
an anode;
a cathode;
an emissive layer disposed between the anode and the cathode, the emissive layer further comprising:
a singlet fission sensitizer, and
a triplet emitter;
wherein the singlet energy of the singlet fission sensitizer is equal to or greater than twice the triplet energy of the singlet fission sensitizer;
the triplet energy of the triplet emitter is less than the triplet energy of the singlet fission sensitizer.

2. The device of claim 1, wherein the singlet energy of the singlet fission sensitizer is within 0.5 eV of the twice the triplet energy of the singlet fission sensitizer.

3. The device of claim 1, wherein the triplet energy of the singlet fission sensitizer is less than 1.7 eV and the triplet energy of the triplet emitter is less than 1.6 eV.

4. The device of claim 1, wherein the singlet fission sensitizer is a host and the triplet emitter is a dopant in the emissive layer.

5. The device of claim 4, wherein the emissive layer consists essentially of the singlet fission sensitizer uniformly doped with the triplet emitter.

6. The device of claim 4, wherein the emissive layer comprises a first sublayer and a second sublayer, wherein:
the first sublayer consists essentially of the singlet fission sensitizer, and
the second sublayer consists essentially of the singlet fission sensitizer uniformly doped with the triplet emitter.

7. The device of claim 6, wherein the emissive layer consists essentially of the first sublayer and the second sublayer.

8. The device of claim 4, wherein the emissive layer comprises a plurality of alternating first sublayers and second sublayers, wherein:
the first sublayer consists essentially of the singlet fission sensitizer, and
the second sublayer consists essentially of the singlet fission sensitizer uniformly doped with the triplet emitter.
